(19) United States
(12) Patent Application Publication
(10) Pub. No.: US 2026/0120219 A1
(43) Pub. Date: Apr. 30, 2026

(54) Wildfire Risk Mitigation Planning with Decision Support

(71) Applicant: Xylo Risk, Inc., Sonoma, CA (US)

(72) Inventors: Scott Farley, Boulder, CO (US); David Winnacker, Albany, NY (US)

(21) Appl. No.: 19/366,911

(22) Filed: Oct. 23, 2025

Related U.S. Application Data
(60) Provisional application No. 63/712,563, filed on Oct. 28, 2024.
(60) Provisional application No. 63/712,561, filed on Oct. 28, 2024.

(51) Int. Cl. G06Q 50/26; G06F 30/27; G06Q 10/0637

(52) U.S. Cl. CPC G06Q 50/265; G06F 30/27; G06Q 10/0637

(57) ABSTRACT

Machine-learning-based methods and systems for vegetation treatment project design. The approach autonomously creates, evaluates, and optimizes wildfire risk mitigation activities to intelligently reduce wildfire risk to communities in a resource-constrained environment. The methods and/or systems are accompanied by a cloud-enabled user interface that provides decision support to vegetation management specialists charged with implementing wildfire risk reduction measures.

### CROSS REFERENCE TO RELATED APPLICATIONS

This patent application claims priority to co-pending U.S. Provisional Patent Application Ser. No. 63/712,561 filed Oct. 28, 2024, and co-pending U.S. Provisional Patent Application Ser. No. 63/712,563 filed Oct. 28, 2024, the entire contents of each of which are hereby incorporated by reference.

### TECHNICAL FIELD

This patent application relates to a machine-learning-based vegetation treatment approach that autonomously creates, evaluates, and optimizes wildfire risk mitigation activities to intelligently reduce wildfire risk to communities in a resource-constrained environment. The methods and/or systems are accompanied by a cloud-enabled user interface that provides decision support to vegetation management specialists charged with implementing wildfire risk reduction measures.

### BACKGROUND

Wildfires are a large and growing problem, particularly in the Western United States, where thousands of residential and commercial properties are burned annually. As widespread development pushes communities deeper into fire-prone ecosystems, more homes and businesses are at risk of wildfire-related loss. Accurate prediction of damage at the structure level is critical to maintaining public safety, incentivizing risk mitigation efforts, and stabilizing residential insurance markets.

Current wildfire risk models are insufficiently accurate to support insurance and local risk mitigation activities. Numerous residential insurance companies have withdrawn from the State of California due to the inability to accurately segment and price wildfire risk. Current risk reduction approaches at the local- and state-government levels are also not based on reliable modeling.

There are many wildfire risk assessment frameworks in use today, both in the public safety arena and for determining underwriting and pricing criteria for insurance companies. All extant wildfire risk assessments depend, at least in large part, but often exclusively, on wildfire intensity (usually measured as flame length through an idealized wildland fuelbed). In addition, most contemporary risk assessments include a probabilistic component, calculated using an ensemble of thousands or millions of simulated fire events. Existing approaches are nearly always wildland-centric, using models of fire behavior and growth designed specifically to capture fire growth across large natural ecosystems.

### SUMMARY OF PREFERRED EMBODIMENTS

A review of recent catastrophic wildfire losses in wildland-urban interface (WUI) communities suggests that using these approaches to evaluate risk in the WUI environment has several important limitations:

Speed Matters: Wildfires that move across the landscape so rapidly that they outpace the ability for communities to evacuate safely and for emergency first responders to arrive and prepare to engage the fire are associated with greater losses than fires that move more slowly. Slow-moving fires are common in timber-dominated environments and often can support flame lengths up to 25′ or more. Fast-moving, wind-driven fires are most common in shrub and grass-dominated ecosystems or the segments of timber-dominated ecosystems with these fuel types. While fire intensity is typically lower, the fire rate of spread can be up to a factor of ten higher in these areas of the landscape than in dense, closed timber stands, even under the same prevailing fire weather conditions. A review of recent urban conflagrations (e.g., the Tubbs Fire, the Marshall Fire, the Camp Fire, the Angora Fire, and the Thomas Fire) indicates that widespread losses occurred when rapidly-moving fire, pushed by extreme winds, entered the built environment with very little response time. Therefore, basing a risk assessment on the fire rate of spread proves to be a better predictor of large-scale urban and peri-urban losses than fire intensity.

Topology Matters: WUI and other peri-urban environments (e.g., suburban, intermix, interface, and rural areas) often support a wide variety of non-burnable or low-burnable landscape features, including golf courses, orchards, parks, electrical and water infrastructure, highways, reservoirs, and agricultural fields. If a fire cannot reach a portion of the built environment, it cannot cause damage to structures. The systems and methods described herein include an in-depth treatment of embers. Embers notwithstanding, however, surface topology is important, because it can determine the extent into the built environment that fire can reach. Many extant fire risk assessments are based on a structure-centric approach, where the conditions proximate to the evaluated building are the only conditions considered for risk (e.g., the average flame length within X meters of the structure or the distance from the structure to the nearest wildland fuels). This negates the important role that built-environment landscape features play in altering, or in many cases, stopping, fire spread on its way into a community. Therefore, incorporating the continuity and topological relationships between fuels capable of carrying fire into the built environment and the existing features that act as firebreaks is an important factor in accurate fire risk prediction.

Density Matters: When fire enters a sufficiently dense area of structures, fire dynamics can shift from being driven by a regime dominated by vegetation-to-vegetation spread dynamics, where fire is pushed across the landscape by well-understood and relatively simple relationships between radiant and convective heat transfer and ember transport, to one of structure-to-structure spread and urban conflagration. This latter mode of fire spread is highly complex and currently not well represented in the scientific literature. What is clear, however, is that the models that are calibrated and effective at predicting fire behavior and growth of vegetation fires are incapable of accurately predicting fire spread within the built environment when conflagration dynamics dominate. Therefore, a risk assessment methodology that provides better handling of structure-to-structure spread and urban connectivity produces a better representation of potential structure damage and loss than one based on wildland-focused fire spread dynamics.

Extremes Matter: Fires that result in catastrophic losses occur under extreme fire weather scenarios. By definition, extremely damaging fires (e.g., the Camp Fire, which destroyed more than 18,000 structures) are low-probability events. Extant wildfire risk models typically generate a probability distribution of fire weather events and model fire behavior and growth probabilistically by using approaches such as Monte Carlo sampling from this distribution. Therefore, existing approaches to risk assessment are biased towards high-probability, low-risk fire weather conditions, which are not the conditions under which large-scale losses typically occur. Particularly in a changing climate, it is likely that these approaches underestimate the risk posed by low-frequency, high-severity events. Therefore, a risk assessment methodology that focuses on assessing fire behavior under locally relevant worst-case fire weather scenarios proves a better predictor of large-scale structure loss.

This patent application describes a novel system and/or method for characterizing wildfire risk that is built explicitly to address the gaps in the existing tools and methodologies identified above.

In brief summary, we describe unique and novel systems and methods for optimizing wildfire risk reduction activities. A machine-learning module generates and evaluates vegetation management treatment opportunities based on wildfire risk data. A fire behavior simulation module computes fire arrival times and fire spread pathways across a landscape. A treatment suitability module computes a spatial, temporally-explicit matrix for vegetation management cost-benefit tradeoff, and a treatment optimization module that iteratively selects treatment locations to maximize wildfire risk reduction within a predefined budget. The systems and methods autonomously select and evaluate treatment opportunities based on fire spread, fuel load, topography, and community risk.

In preferred embodiments, data representing estimated fire spread pathways are used to construct a directed graph. Nodes in the directed graph represent geographically-located points and edges in the graph represent fire spread between the points. The graph enables improved and efficient centrality and hub-based analysis for prioritizing mitigation treatment plans and their locations.

In one example, wildfire risk mitigation planning may include optimizing vegetation management, such as by simulating fire spread pathways using fire behavior data under extreme fire weather scenarios, filtering simulated fire spread pathways to retain those representing worst-case fire behavior, constructing the graph of fire spread pathways with nodes representing geographic points and edges representing potential fire spread, evaluating the cost-adjusted suitability of treatment at each point on the landscape with respect to reducing community risk, and iteratively selecting treatment opportunities that maximize risk reduction within a budget, wherein the method terminates when a predefined budget is exhausted or marginal risk reduction falls below a threshold.

The selection of treatment opportunities may be based on the centrality of nodes in the fire spread graph, with nodes having higher centrality or hub scores prioritized for treatment.

A region-growing algorithm may be used to select the initial high-suitability nodes and iteratively add contiguous nodes until a maximum treatment size or suitability threshold is reached.

A treatment optimization module may use an evolutionary learning algorithm to generate a population of potential treatment opportunities, mutate and crossover subsets of treatment opportunities, and select the optimal treatment set based on a fitness function that incorporates fire arrival times, structure risk, and budget constraints.

In some implementations, fire behavior is simulated using fire weather scenarios based on historical wind data, wind speed, relative humidity, and fuel moisture content.

The systems and methods may also simulate post-treatment fire behavior and for example, calculate the difference in fire arrival times at structures or values at risk, to quantify the effectiveness of the treatment plan.

Treatment opportunities may be prioritized based on their proximity to community values at risk, such as residences, infrastructure, or other critical facilities.

The systems and methods may integrate with a decision support system tailored for wildfire risk reduction. The decision support system may utilize a user interface configured to display fire pathway simulations and treatment opportunities on a geospatial map,

The results may be provided as a ranked list of treatment opportunities based on their expected impact on reducing fire arrival time and protecting community values at risk

Users may provide inputs that adjust parameters of the optimization, such as budget and area of interest

A treatment optimization module may be used to identify solutions that minimize total treatment cost while maximizing fire arrival time at community values at risk. For example, treatment opportunities are selected based on their ability to reduce the fire rate of spread over untreated conditions.

The systems and methods may interface to one or more geographic information systems (GIS) to import terrain, fuel, and weather data, and to export treatment plans and fire pathway simulations for external use in standard GIS formats.

The fire behavior may simulated using external fire modeling software, with results imported into the system for treatment evaluation and risk quantification.

A treatment optimization module may evaluate treatment opportunities based on their projected impact on reducing fire arrival time at community values at risk, with the system prioritizing opportunities that significantly delay fire arrival within constraints.

An optimization process may terminate when the marginal impact of additional treatment opportunities on fire arrival time reduction is less than a predefined threshold, ensuring cost-effective allocation of resources without over-treating areas with diminishing returns.

A treatment suitability matrix may be dynamically adjusted by calculating the derivative of treatment suitability values in relation to the axis of fire growth, such that cells perpendicular to the axis of fire growth are given higher suitability scores than those aligned with the fire spread direction.

Such a suitability matrix may be dynamically adjusted to promote treatments that span a limited number of parcels and land ownership jurisdictions, or to promote treatments that span a single vegetation type.

In some implementations, fire spread pathways are identified using a Minimum Travel Time (MTT) algorithm, so that treatment opportunities can be selected based on the interruption of the fire spread pathways, reducing a likelihood of a rapid fire reaching community values at risk.

The systems and methods may also iteratively allocate a portion of a constraint, such as a total budget, to sequential tranches of treatments, adjusting subsequent allocations based on the effectiveness of previously applied treatments, and thus optimizing the distribution of funds throughout the treatment process.

After application of each tranche of treatments, the fire behavior simulation module can be re-run to update fire spread pathways, enabling the system to focus subsequent tranches on untreated high-risk areas.

In some implementations, fire spread pathways are simulated under extreme fire weather scenarios, including historical or synthetic conditions characterized by high wind speeds, low humidity, and critical fuel moisture levels, to ensure treatment opportunities address worst-case fire behavior.

Each of the fire spread pathway may be evaluated based on the number of structures it threatens, with the system back-propagating the threat through the fire spread graph to identify critical trunk segments where fire spread poses a significant risk to downstream structures, prioritizing treatment opportunities along pathways that impact highly developed areas with a large number of buildings.

A system or method may may be configured to include one or more cloud-based backend processing resources and database(s) to facilitate handling requests and storing run metadata.

### BRIEF DESCRIPTION OF THE DRAWINGS

FIG. 1 is a high level diagram of an example system showing data flows and processing modules.

FIG. 2 is an example map showing ignition lines and fire pathways from two different wind scenarios.

FIG. 3 is an example flow for constructing a topologically-aware graph.

FIG. 4 is an example threat assessment process.

FIG. 5 is an example of graph-based fire pathways in Paradise, California.

FIG. 6 is an example directed graph.

FIG. 7 is an example state transition.

FIG. 8 illustrates composite treatment suitability for a portion of Contra Costa County, California.

FIG. 9 is an example flow for treatment optimization.

FIG. 10 is an example of treatment opportunity placement.

FIG. 11 shows how the treatment plans may be constrained.

FIG. 12 is an example of how a multi-objective fitness function may be determined.

FIG. 13 is an example evolutionary learning loop.

FIG. 14 illustrates fitness components evaluated for 250 iterations of the evolutionary learning algorithm.

FIG. 15 is an example region growing flow.

FIG. 16 shows how the populations of regions may converge to an optimal set.

FIG. 17 shows how a treatment plan may be evaluated.

FIG. 18 shows the delay in fire arrival time attributable to a treatment plan constructed using the methods described herein.

FIG. 19 is an example traunche process.

FIG. 20 is an example information flow between components of the user interface.

FIG. 21, FIG. 22, FIG. 23, and FIG. 24 show several examples of the user interface in action.

### DETAILED DESCRIPTION OF PREFERRED EMBODIMENTS

### Introduction to Vegetation Treatments

Vegetation management wildfire risk mitigation projects (i.e., thinning, prescribed fire, mastication, grazing) are often extremely expensive (>$1,000 acre), occur on difficult-to-access terrain, are subject to a wide variety of environment constraints, and have different efficacies, depending on the site-specific conditions within the project. Although numerous local, state, and federal vegetation management projects are currently planned and underway to reduce the risk to Wildland-Urban Interface (WUI) communities, these projects are generally not developed using hard science. Instead, convenience, logistical feasibility, and political pressures often dominate the choice of methods and areas treated. Furthermore, vegetation management alone cannot eliminate wildfire risk, particularly in areas of dense WUI and peri-urban development. In these areas, it is important to complement vegetation management with effective on-parcel mitigations, such as defensible space and home hardening. Both approaches must be present to create a fire-resilient community.

Budgets to undertake both vegetation management and on-parcel risk mitigation projects are severely constrained. Although fire suppression is well funded by state, local, and federal government entities, fire preparedness and prevention are not. Therefore, budget constraints limit the number and type of projects that can be undertaken to mitigate the risk to communities. In this resource-limited environment, improving the efficacy of each project can vastly improve the capacity for limited budgets to effectively improve community safety and reduce widespread wildfire losses.

The systems and methods described herein are a novel, machine-learning-based approach to designing treatments that optimally reduce community wildfire risk for a given constraint, such as a resource like a budget. In one example, for a given budget (in acres or in dollars), mitigation projects are iteratively added in the areas of the landscape that best reduce risk to downwind and adjacent communities. As projects are added, the risk to some portions of the community is reduced, and new areas become a higher priority for mitigation. Projects are identified, mapped, and evaluated autonomously by a machine-learning system that creates an overall mitigation strategy that terminates when the constraint (such as a budget) is exceeded, or some other constraint, such as when fast-moving fire is no longer likely to reach the community, or when diminishing marginal returns are reached. Through a map-based decision-support user interface, the system may provide a prioritized view of mitigation opportunities, data-driven insights into each opportunity, and contextual layers to help better understand the potential for wildfire risk reduction activities.

This optimized mitigation approach has been validated and shown in several studies around California to vastly reduce the quantity and expense of wildfire mitigation projects needed to preserve community safety.

### INTRODUCTION

This work introduces an iterative mitigation strategy design algorithm that incorporates landscape topology, fire behavior, physical feasibility, and cost to prioritize fire risk mitigations that optimally reduce fire risk to the built environment.

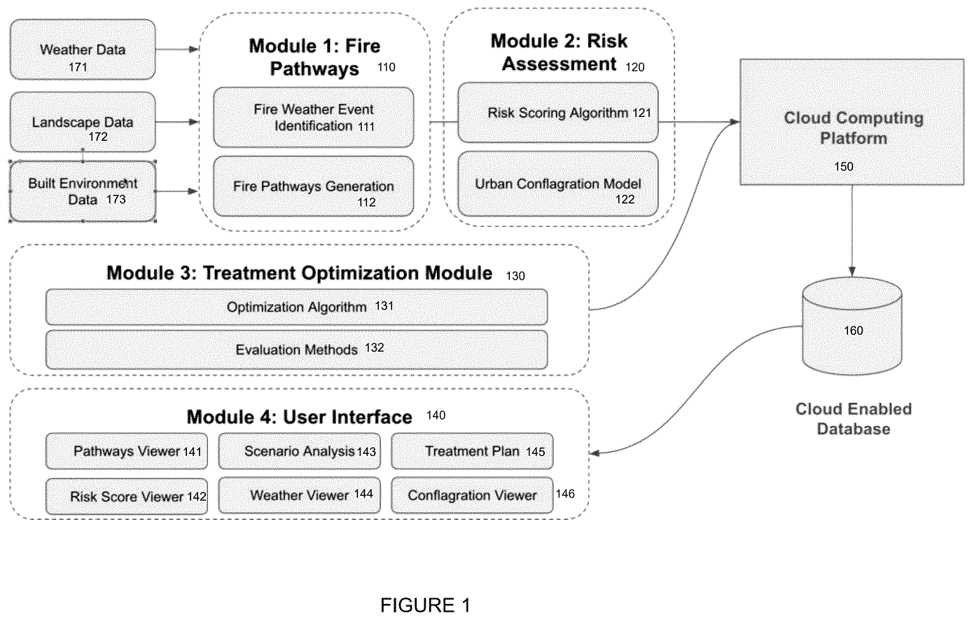

FIG. 1 is a high level diagram illustrating data flows and processing modules in an example system or method.

Briefly, inputs to a typical system 100 include weather data 171, landscape data 172, and built environment data 173. The inputs drive a set of processing modules. Module 1, Fire Pathways 110, includes a fire weather event dentification function 111 and a fire pathways generation function 112. Module 2, Risk Assessment 120, includes a risk scoring algorithm 121 and an urban conflagration model 122. Module 3, a Treatment Optimization Module 130, includes an authorization algorithm 131 and evaluation methods 132. Module 4, a User Interface 140, includes a number of functions, including a pathways viewer 141, a risk score viewer 142, a scenario analysis 143, a weather viewer 144, a conflagration viewer 145, and a treatment plan viewer 146.

These modules 110, 120, 130, 140 and their associated functions are preferably implemented within one or more data processing components, such as a cloud computing platform 150 and one or more cloud-enabled databases 160. However, it should be understood that while cloud computing provides the preferred arrangement, these modules and functions could also be implemented in whole or in part on other types of data processing platforms, such as one or more physical, and/or virtual machines with associated physical disk, non-volatile storage, memory, and processing units.

Machine Learning for Autonomous Optimization: One or more of the modules 110, 120, 130, 140 preferably leverage machine learning where possible and advantageous. The use of machine learning to automatically identify, evaluate, and optimize vegetation management projects for wildfire risk reduction enables the system to iteratively refine treatment strategies based on performance metrics. This data-driven approach is uncommon in wildfire risk mitigation, where decisions are often made manually or based on heuristic models.

Fire Pathway Analysis Using Minimum Travel Time (MTT): A framework based on a Minimum Travel Time (MTT) algorithm delineates fire spread trajectories under extreme fire weather scenarios. This enables the identification of high-risk areas where fast-moving wildfires have the greatest potential to cause catastrophic loss in peri-urban environments.

Topologically-Aware Fire Spread Modeling: A directed graph structure is used to model fire spread topologically, allowing for the identification of critical “hub” nodes that facilitate fire spread and enables the assessment of cumulative threat to downstream structures and other values at risk, enhancing the precision of risk mitigation strategies.

Cost-Adjusted Treatment Suitability Surface: A multi-layer geospatial model is constructed to produce a cost-adjusted treatment suitability surface, identifying high-value project areas that are both logistically feasible and ecologically suitable for vegetation management, ensuring that resources are allocated efficiently.

Region-Growing Treatment Construction Algorithm: A region-growing algorithm iteratively constructs treatment geometries by selecting nodes based on their suitability and adjacency. This autonomous process creates treatment areas that effectively interrupt fire growth vectors, enhancing the system's ability to mitigate fire spread.

Multi-Objective Fitness Function: A multi-objective fitness function evaluates treatment opportunities based on multiple criteria, ensuring not only high project suitability but also geographic dispersal of treatments, preventing over-concentration of resources in one area, and ensuring broader landscape protection.

Iterative Construction Based on Available Resources: The treatment plan is designed using an iterative process that adheres to a user-provided budget constraint. Treatment opportunities are added incrementally in “tranches,” each of which uses a portion of the available budget to reduce fire spread through a network of strategically placed treatments. After each tranche is virtually implemented, the fire simulation is re-run to assess the effectiveness of previously applied treatments. This approach enables the system to identify areas already protected by earlier treatments and directs subsequent tranches to focus on unmitigated high-risk areas, ensuring that resources are efficiently allocated to maximize wildfire risk reduction.

Termination Condition Based on Diminishing Marginal Returns: The system includes a termination condition based on the diminishing marginal returns of additional treatments, ensuring that resources are not wasted once further interventions provide minimal additional benefit in delaying fire arrival.
Treatment Optimization
Module 1: Fire Pathways 110
Minimum Travel Time Algorithm

A fire pathways module 110 serves to delineate the paths of least resistance for fire spread across a landscape-identifying trajectories along which wind, topography, and fuel are likely to align under catastrophic fire weather conditions. Pathways may be calculated using Finney's 2002 Minimum Travel Time Algorithm (MTT) (Finney, Mark A. “Fire growth using minimum travel time methods.” Canadian Journal of Forest Research 32.8 (2002): 1420-1424) This algorithm deconstructs a set of raster data layers, where each pixel (or “cell”—the terms will be used interchangeably herein) represents a distinct characteristic, into a structure with nodes connected by edges along which fire can travel. Spatial data layers used in this algorithm include elevation, slope, topography, fuel model, canopy cover, canopy height, canopy base height, and canopy density. The rate of spread along each edge may be calculated using Rothermel's rate of spread equations (See Andrews, Patricia L. “The Rothermel surface fire spread model and associated developments: a comprehensive explanation.” (2018): vi+-121) and is adjusted for alignment with the wind and slope vectors along that edge. Subsequently, a least-cost pathfinding algorithm is applied to identify the fastest (lowest-cost by time) paths from a user-specified ignition location to every node in the graph within a user-provided simulation duration.

The results of this algorithm include:
(a) sequences of nodes and edges from the ignition source to the simulated fire boundary, indicating the fastest route of fire travel,
(b) simulated fire arrival time at each node in the graph, and
(c) other fire behavior characteristics at each node, including flame length, rate of spread, and spotting potential.

### Fire Weather Event Identification 111

This analysis is concerned with characterizing the potential for extreme fire behavior and mitigating fire growth rates under extreme weather conditions. Therefore, fire pathways are run using locally extreme fire weather conditions. Wind events are identified from the historical record, using reanalysis and/or surface weather observations to identify events demonstrating:
Sustained high winds
Low relative humidity during periods of generally low atmospheric moisture
End of the growing season, when live fuels are cured

Wind events can also be selected to correspond with historical fires in the area. For example, in Paradise, CA, it could be most appropriate to use the weather on Nov. 8, 2018, which drove the Camp Fire to catastrophic losses. Scenarios based on weather data accompanying historically damaging fires in the area often demonstrate the qualities listed above.

Whether based on recent fire activity or analysis of historical weather data, Fire Weather Scenarios (FWS) are developed to specify values for:

Wind speed: Maximum realistic wind speed likely to drive fire growth during peak fire season

Wind direction: Direction from which maximum wind speed is likely to come from

Relative humidity: Atmospheric moisture during the wind event, expressed as a percentage of saturation, used to determine the moisture content of fine dead fuels (1-hour)

Daily average relative humidity: Atmospheric moisture content during wind event, used to determine the moisture content of large dead fuels (10 and 100-hour)

Live fuel moisture: Moisture content of live fuels (grasses and herbaceous shrubs), derived from a database like the US Forest Service's Live Fuel Moisture Database.

Often, two or more FWSs are developed to indicate potential fire weather conditions from multiple wind directions. Table 1 shows the FWSs used for modeling in an example for San Luis Obispo, CA.

TABLE 1
FWS weather parameters for modeling in San Luis Obispo, CA.

| | Scenario 1: | Scenario 2: |
|---|---|---|
| | South Wind | West Wind |
| Wind Speed | 15 | 15 |
| (mph) | | |
| Wind Direction | 163 | 293 |
| (degrees) | | |
| Relative Humdity | 3 | 2 |
| Daily Average | 12 | 12 |
| Humidity | | |
| Live Fuel | 60 | 95 |
| Moisture | | |
| Weather Station | Arroyo Grande | Arroyo Grande |
| Representative | Oct. 28, 2010 | Sep. 6, 2015 |
| Date | | |

### Fire Pathway Generation 112

For each FWS, a simulated ignition is then identified upwind of the community being modeled. Fire pathway generation makes the assumption that a large and established fire front has already developed on the landscape. The model illustrates the most probable paths of the fire growth downwind from this established front. Ignition locations (which may be points, lines, or areas) can be generated algorithmically or via manual specifications from fire officials or model developers.

Simulations can be run for any duration; however, given this analysis' focus on fast-moving fire that may outpace evacuation and firefighter response, simulations are generally constrained to 8-18 hours. After 18 hours, civilians are likely to have evacuated, and firefighters to have assembled a sufficient response force to prevent conflagration.

The ignition line and FWS parameters are then input into a Minimum Travel Time (MTT) algorithm such as the one developed by the U.S. Forest Service's Missoula Fire Lab (that is, the Fire Behavior and First Order Fire Effects calculations produced with the command line applications developed by the Missoula Fire Sciences Laboratory, Missoula, MT currently available at https://github.com/gagreene/US_FireModelling_Automation). The outputs from this process include compatible files from the geographic information system (GIS) that are used for subsequent analysis.

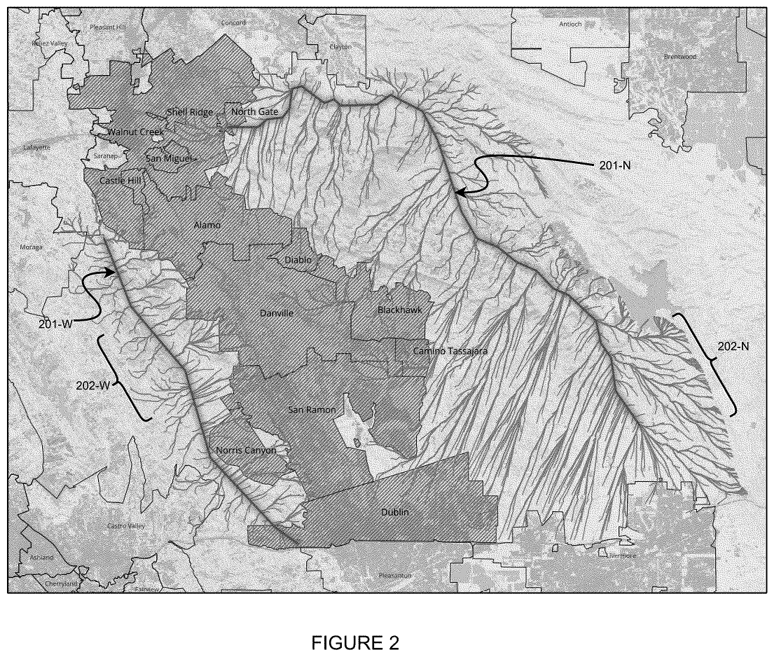

FIG. 2 is an example fire pathways output showing ignition lines (in red or bold) and fire pathways (in orange) from two different wind scenarios: a north wind (on the right side of the map) and a dry west wind (on the left side of the map).

### Pathways Post Processing

When pathways are output from the MTT software, they may be represented as directionless line strings in Environmental Systems Research Institute (ESRI™) Shapefile™ format, where each line represents a potential MTT path of fire across the landscape from the ignition point to the boundary of the simulated fire at the specified simulation duration. These pathways typically require postprocessing to be effectively used in subsequent treatment optimization process.

### Filtering

Fires spread most rapidly when aligned with wind and topography. Although fires can also spread against the wind or downhill, the growth rate of backing or flanking fires is typically much slower than that of head fires, which move in the direction of alignment. The MTT software generates outputs for both backing and head fires, resulting in some paths that lead upwind from the ignition source. However, these upwind paths are not useful for assessing worst-case fire behavior, as they typically grow 10 to 100 times more slowly than paths aligned with the wind.

To filter out pathways that represent inconsequentially slow growth, the Fire Pathways Generation 112 process may further select pathways whose length is less than 25% of the length of the maximum pathway in the simulation are removed. Formally, pathways may be filtered based on the condition:
Where:
is the length of pathway.
is the length of the longest pathway in the simulation
is a threshold factor

### Graph Construction

Fire spread topology plays a crucial role in identifying high return-on-investment treatment areas. While the MTT algorithm constructs an internal graph of fire travel, this structure is not included in the standard output. Therefore, a custom, topologically-aware graph data structure may be built from the raw MTT outputs to capture relationships between fire pathways and enable graph-native calculations, such as determining a node's centrality or its tendency to function as a hub.

An example topologically-aware graph can be constructed by a graph generation mofule for each fire simulation by iterating over the paths in the simulation output.

Let represent a directed graph, where:
is the set of nodes, corresponding to geographically located points,
is the set of directed edges, representing potential fire spread between nodes.

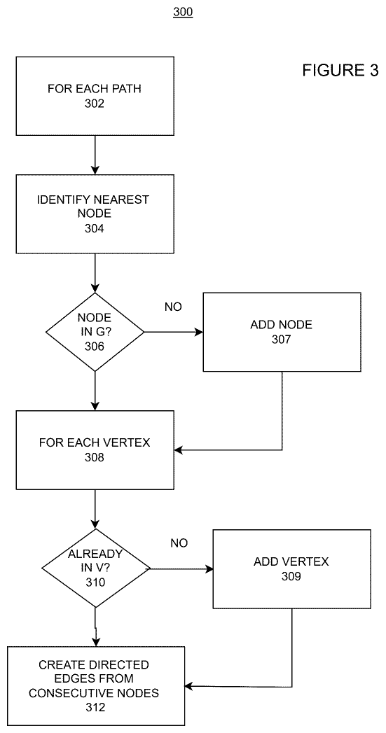

FIG. 3 illustrates an example flow 300. For each path (step 302) in the filtered outputs:

Identify (step 304) the node located at (or nearest to) the ignition point. If this node does not exist in (step 306), add it to (step 307).

For each vertex (step 308) along the path's line string, check (step 310) whether it is already present in. If not (step 311), add it to the set

For each consecutive pair of nodes along the path, create (step 312) a directed edge where represents the source node and represents the destination node in the direction of fire spread.

### Module 2: Pathway Risk Assessment

Fires that threaten a large number of structures pose a greater hazard from a community safety and loss perspective compared to those that reach fewer structures. Therefore, pathways leading to highly developed areas should be scored, or prioritized for mitigation. To quantify this, each edge in the graph may be further evaluated for the number of combustible fuel sources (community assets such as buildings, structures, infrastructure, or other assets at risk) it impacts. The impact of fire spread is then back-propagated through the graph, identifying “trunks” of fire spread-key segments where fire can potentially threaten many downstream structures.

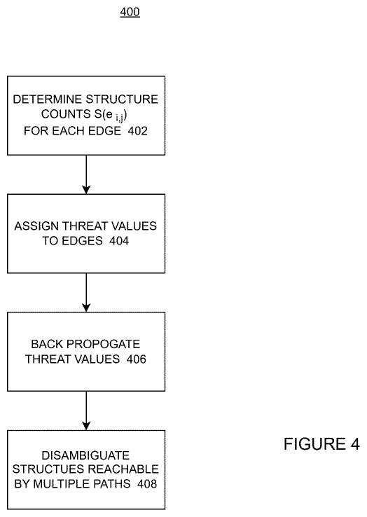

An example pathway threat assessment function 400 proceeds as shown in FIG. 4.

Structure Count Calculation: For each segment/edge in the graph, the number of structures within a 100-meter buffer of the pathway is identified and counted (step 402).
For each segment (edge), representing the connection between nodes and, the number of structures within a 100-meter buffer of the segment is denoted as. Mathematically:
where:
   is the total number of structures,
   is the distance from structure to edge,
   is an indicator function that returns 1 if (i.e., the structure is within 100 m of the edge), and 0 otherwise.

Threat Assignment: Each edge in the graph is then assigned (step 404) a threat value proportional to the number of structures it affects directly.

For example, each edge is assigned a threat value) proportional to the number of structures affected directly by that segment: where is a function that converts structure counts into threat values, potentially weighted by factors like structure density or value.

Backpropagation of Threat: The threat values are back-propagated (step 406) along the graph's edges, ensuring that upstream segments reflect the cumulative threat posed by downstream structures. This highlights critical “trunk” pathways that have a significant downstream impact.

The threat values are backpropagated along connected edges. For an edge, the backpropagated threat is the sum of its own threat and the threats from all downstream edges:
where:
is the set of downstream nodes connected to,
is the backpropagated threat from edges downstream of.

Disambiguation of Structures: To avoid double counting, structures that are reachable by multiple paths within the same trunk are only counted once (or “disambiguated”) (step 408). This ensures that the threat values represent unique buildings affected by the pathway.

For each node, let represent the set of unique structures reachable by any path originating from:

The threat value of a pathway originating from is then based on the size of.

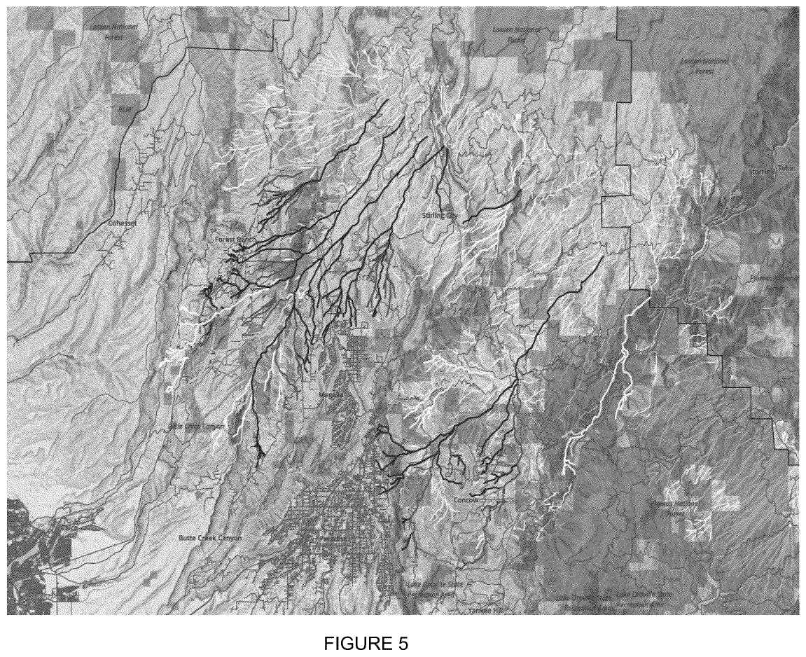

FIG. 5 is a visual representation rendered from such a graph. Here, the graph-based fire pathways for Paradise, CA were determined, where each segment is symbolized by the number of distinct downstream buildings it affects. In this example, the paths rendered in the color white indicate paths where few structures are affected, while darker shades (such asred) represent paths having many affected structures.

### Centrality Measures

Nodes from which many paths diverge are ideally suited for prioritized vegetation management, as fuel treatments in these areas can prevent fire from spreading in multiple directions and potentially affecting many different parts of the community. To facilitate the identification of these key locations, each node in the graph may be further evaluated for centrality measures, including the directed degree of centrality and its tendency to form hubs.
1. DirectedDegree of Centrality: The directed out-degree centrality of a node is the number of edges originating from, representing the number of pathways diverging from that node.
Mathematically, the out-degree centrality is defined as:
where:
is an indicator function that returns 1 if there is an edge from to, and 0 otherwise,
is the set of edges in the graph.
2. Tendency to Form Hubs: Nodes that act as hubs play a critical role in fire spread by connecting multiple pathways. The tendency of a node to form a hub can be assessed using hub centrality measures, which evaluate the node's importance based on both its out-degree and the influence of the nodes it connects to. The hub centrality score is given by:
where:
is a scaling factor (typically between 0 and 1),
refers to the set of nodes directly reachable from,
is the hub centrality of node

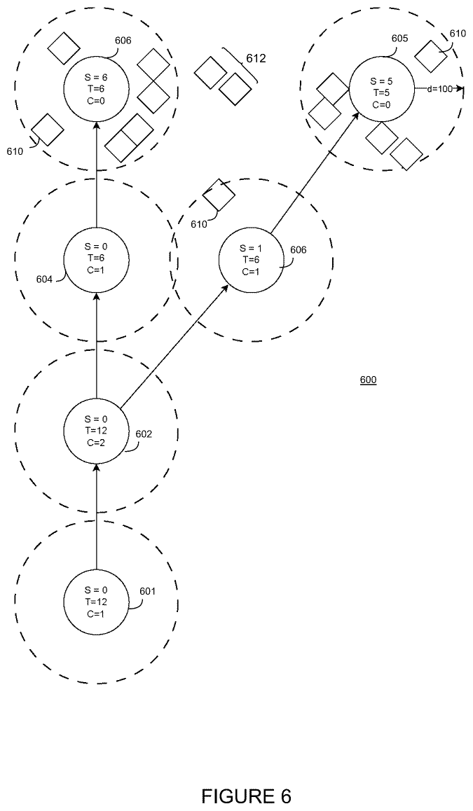

FIG. 6 is an example directed graph 600. In this example, there are six nodes 601-606 representing six distinct segments. Three of the nodes (601, 602, 604) have no associated structures within the associated 100-meter buffer, so the number of structures S(eᵢⱼ) associated with this node is zero (shortened to “S” in the figure). Node 603 has a single structure; node 605 has five structures and node 606 has 6. Note some structures 612 lie outside of any segment and thus are not considered. Note also that some segments may overlap in space with one another such as those associated with nodes 603 and 604.

Node 601 is the most centrally located node and thus assigned a C_{hub}(vⱼ) value of 1 (denoted as “C” in the figure) indicating a “centrality” metric for the node. Nodes 602, 603, etc. that are progressively farther away from node 601 have increasing C values.

Values T(eᵢⱼ) may also be associated with the graph, which represent the tendency for each node to form hubs (as described elsewhere).

It should be understood that FIG. 6 is intended as an example only, and that other values and attributes of the fire spread models and treatments may be associated with the nodes or edges in the graph.

### Predicting Post-Treatment Fuels

Vegetation management for fire risk mitigation modifies surface fuel continuity and arrangement and, in some cases, canopy coverage, density, and height through interventions like tree thinning and removal. Treatments can take many forms, including mechanical thinning, mastication, hand thinning, selective tree removal, invasive species removal, broadcast burning, pile burning, herbicide application, and targeted grazing (herbivory). The choice of treatment(s) depends on site-specific characteristics such as vegetation type, slope, fuel loading, available budget, local resources and expertise, and regulatory constraints.

While exact specification of treatment prescription is difficult to develop without detailed site inspections, it is possible to broadly estimate the post-treatment fuel conditions based on current landscape characteristics—fuel loading, vegetation type, and slope—and assumptions about likely treatment activities for different site configurations.

One approach employs a heuristic state-transition model to assign a probable treatment type to each cell in the landscape. The model then predicts the likely post-treatment surface fuel model based on pre-treatment conditions and the chosen treatment activity.

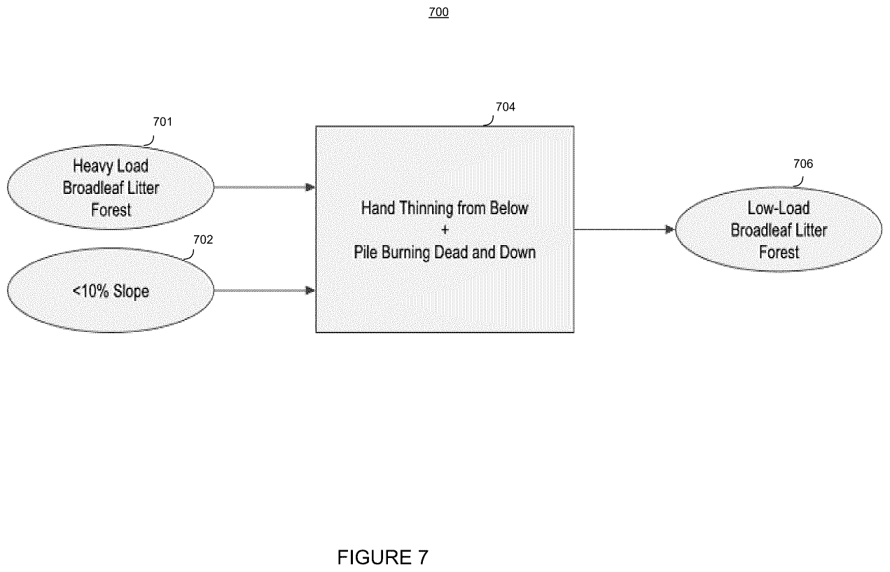

FIG. 7 shows an example result 700 where astate transition was based on the analysis ruleset. Here the initial state was a heavy load broadleaf forest 701 using standard fuel model 186 on a low slope site 702 (<10% slope). Hand thinning from below with pile burning (704) was the applied treatment. Post-treatment, the resulting state is transitioned to a low-load broadleaf filter fuel mode 182 (706)

Using this state transition model, a potential post-treatment fuel model is assigned to every pixel in this study area. This updated fuel model represents the potential fuel loading and arrangement at the conclusion of the vegetation management activity on that pixel. Each pixel's treatment activity and potential post-treatment state are calculated independently (i.e., there is no attempt to constrain like-treatments next to one another).

### Estimating the Effectiveness of Vegetation Management

Both the pre-treatment (i.e. current) fuels layer and the potential post-treatment fuels layer may be used to compute pre- and post-treatment estimates of fire behavior such as by using the Flammap fire modeling package available from the USFS Missoula Fire Lab. The FWS inputs are held constant across both runs; therefore, the difference in fire behavior between the two runs is strictly attributable to the changes in fuel loading and arrangement afforded by vegetation management.

Here the process is most concerned with slowing fire growth and limiting the fire's capacity to make long, uninterrupted runs towards community values at risk. Therefore, the fire behavior characteristic of greatest interest here is the rate of spread (ROS). ROS may be expressed in chains per hour or feet per minute, and is a measure of how quickly a head fire burning in alignment with the wind would burn across that cell. Other measures of fire behavior, such as fire intensity, crown fire transition probability, or spotting distance, could also be included a future iteration of this analysis.

The effectiveness of vegetation management is quantified by assessing the difference in ROS between the pre- and post-treatment fire behavior runs.
Where:
is the change in rate of spread
is the treated rate of spread is the current rate of spread

To facilitate inclusion in the rest of the analysis, values for are capped between −100 and 100 and then reclassified on a scale of 0 to 5, where zero indicates little change and 5 indicates a large change.

### Treatment Suitability

The potential suitability of a wildfire-focused vegetation management project depends on its benefits and costs.

From a benefits perspective, high-suitability projects are those that:
Are located in areas where fire intensity and/or fire rate of spread is high
Are located along a fire pathway and in areas with a large number of downstream values at risk (structures, residences, and/or infrastructure)
Are located in fuels where vegetation management can effectively reduce fire intensity and/or rate of spread
Are located in areas where many fire pathways diverge
Are located close to community developments

From a cost perspective, high-cost projects are those that:
Are located in inaccessible areas, such as those far from roads
Are located in steep slopes or otherwise challenging terrain
Are located in areas of regulatory or environmental sensitivity

In a preferred embodiment, this model creates a planning agent that optimizes these cost-benefit tradeoffs and produces a network of viable treatment project sites. To achieve this objective, a treatment suitability map layer is first produced to guide the assessment of costs and benefits at each potential project location.

Let) represent the coordinates of each pixel on the landscape, and let be the overall suitability value for that pixel. (Note in this section, “S” is defined to be a suitability value for a pixel; elsewhere “S” was used to represent the number of structures associated with a node in the graph). The suitability value S is calculated as the weighted sum of benefits minus the weighted sum of costs, where each layer is reclassified to a scale from 0 to 5 and has an associated weight. These weights λₓ may be provided by a user of the system, such as a developer, based on their local knowledge or expert judgement.

For each pixel, the suitability is defined as:
where:
   is the value of the -th layer at pixel, reclassified onto a scale of 0 to 5
   is the weight associated with the -th layer
   is the total number of layers considered in the analysis.

Layers may include:
Change in fire rate of spread attributable to vegetation management
Untreated fire rate of spread
Backpropagated segment threat score
Distance from roads
Slope
Node centrality
Node Tendency to Make Hub
Distance to community values at risk

Each layer has a weight, allowing for the flexibility to adjust the relative importance of the different factors in the analysis.

Note that because the suitability calculations depend explicitly on the graph topology (node centrality and backpropagated threat score), pathway geometry, and fire weather parameters (used to calculate potential fire behavior), each fire simulation will result in its own treatment suitability layer.

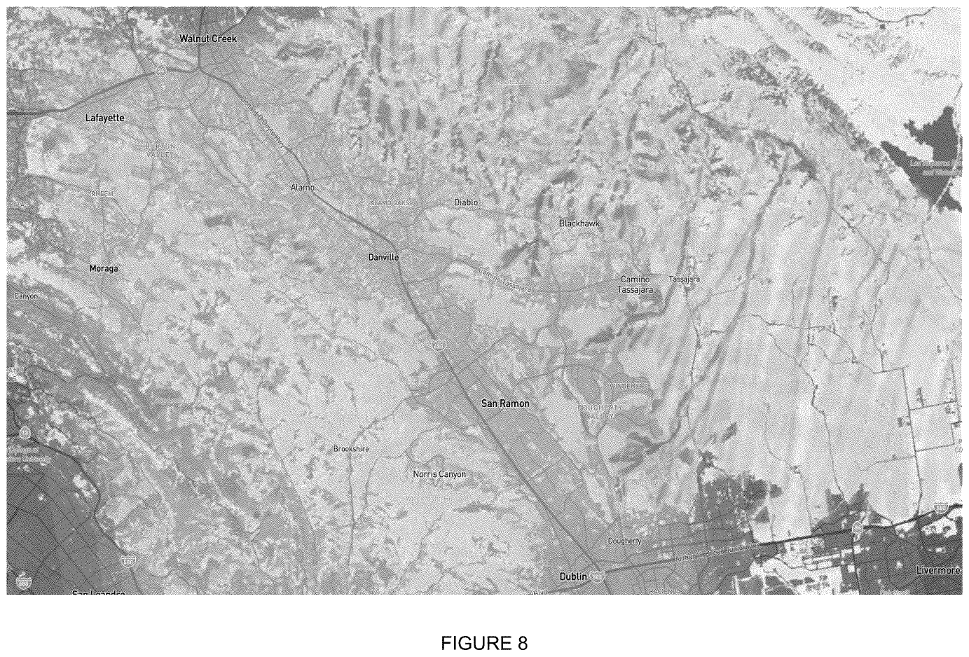

FIG. 8 is an example rendering of the composite treatment suitability for a portion of Contra Costa County, California.

### Module 3: Treatment Optimization 130—Overview

Returning briefly to FIG. 1, treatment optimization employs am autonomous learning agent to iteratively identify and select the best subset of potential treatment locations given some constraint, such as a budget or some other limitation (such as time or risk). In selected implementations, the most common constraint is a budget in dollars, but other constraints may include the number of acres that the customer has capacity to treat, the number and capabilities of the staff they have available to do the work (i.e., do they have a machine for masticating the understory, or do they have a hand crew that uses chainsaws, which is slower and provides different results). Ultimately, it all comes down to costs in money and/or time, may be expressed in different units by the user, based on their unique needs.

This module 130 identifies beneficial networks of Strategically Placed Local Area Treatments (SPLATS), and has been shown to produce high return-on-investment treatment projects in several spatial and ecological contexts. Potential treatment locations may be areas of about 10-30 acres combined into a network that specifies fuel reduction in strategic areas of the landscape to create barriers to rapid fire spread and increase the amount of time a fire would take to reach the community's values at risk. Note that treatment plans are designed to function together—the impact of a treatment plan is more than the sum of its component parts in interrupting and slowing rapid fire growth.

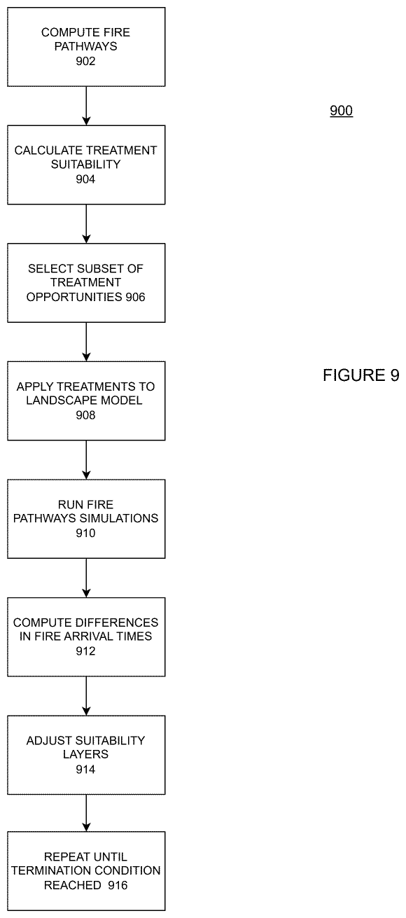

FIG. 9 is an example flow 900 for treatment optimization 131. In general, the algorithm works as follows:

Fire pathways are computed (step 902) using one or more locally relevant FWS

Treatment suitability is calculated (step 904)

Possible treatment opportunity polygons are located across the landscape. Each potential opportunity is evaluated, and a subset of the opportunities are selected (step 906). This subset or “tranche” of opportunities is the optimal network of treatments, given the current landscape conditions, the specified potential fire weather, and a given budget constraint

Treatments are virtually “applied” (step 908) to the landscape by updating the base fuels dataset.

Fire pathway simulations are re-run (step 910) under the same FWS parameters.

The difference in fire arrival time is computed (step 912) between the simulations that used the pre-treatment fuels and the one that used the post-treatment fuels.

Suitability layers are adjusted (step 914) to:
(a) Remove already-treated opportunities
(b) Update pathways to reflect the fuel adjustments resulting from vegetation management
(c) Penalize treatment opportunities in areas that benefit from an upstream treatment, ensuring treatments are positioned to benefit all of the community's values at risk and not the over-treat particular areas of the landscape.

The above process is repeated (step 916) until a termination condition is reached:
(a) No more areas are available for treatment
(b) The user-specified budget for treatment is exceeded
(c) Community risk has been reduced below a pre-determined threshold
(d) The added benefit of additional treatments is less than a pre-determined marginal benefit threshold.

This approach has several important differences from common fuel treatment planning strategies:

Intensity is not considered: Intensity is an important component of fire-risk-focused vegetation management planning if the treated area is likely to be used by ground-based suppression resources in controlling or containing the fire. However, because they are often located far from roads and other anchor points, SPLATS are not designed to be used in direct fire suppression. Instead, they are designed to modulate fire behavior, and in particular, to slow the fire's rate of spread in strategic locations, without firefighter intervention. Firefighters instead focus on structure defense in and around community values at risk, benefiting from the SPLATS through increased fire arrival time. Therefore, this work's goal is to identify areas where the rate of spread can be optimally reduced without considering the potential changes in fire intensity at those locations (e.g., flame length, fireline intensity, heat per unit area, or other common fire behavior indicators).

Spotting is often an important element of fire spread. Spotting can occur when a fire is sufficiently hot, and fuels have sufficient vertical continuity, to move from the surface into the canopy. From the canopy, wind-driven embers can be cast into the prevailing winds and, potentially, ignite spot fires ahead of the main fire front. Therefore, reducing fire rate of spread can also encompass reducing fire spotting potential. In a future iteration of this work, additional criteria to determine spotting distance and direction, spotting's effect on overall fire spread rate, and vegetation management's role in reducing that spotting will be introduced to the treatment optimization algorithm.

Linear fuel breaks are not considered: Most community-safety-focused wildfire risk reduction vegetation management occurs in the form of linear shaded or unshaded fuel breaks that create contiguous rings of fuel reduction directly around values at risk. While fire must necessarily burn through these areas to reach the community, linear fuel projects have several drawbacks that can be addressed with SPLATS:
(a) Treatment projects directly adjacent to the community are those most likely to intercept fire spread under any wind/weather scenario. However, they are not well-suited to sufficiently slow fire growth to facilitate civilian evacuation and emergency response, because they are often only tens or hundreds of feet from the community's values at risk. Even if the fire burns slowly through the treated area, fire is often already too close for the project to provide more than a few minutes of additional arrival time, particularly if the fire is driven by spotting ahead of the main fire front.
(b) Linear treatment projects often have portions of relative inefficiency. Vegetation management efficiency, and therefore return on investment (ROS), depends on many factors, including the fuel type, site slope, wind alignment, and type of treatment applied. By creating a ring around the community, many areas of the project are likely to be out of alignment with wind and topography and/or located in areas of minimal threat (e.g., areas with low rate of spread). SPLATs are designed to identify the treatment areas with the greatest return on investment, reducing the portions of the landscape where vegetation management has relatively little effect on fire behavior and community safety.

### Module 3: Treatment Optimization 131—Different Methods

Opportunity Selection—Method 1—Enumerated Opportunities and Evolutionary Learning

Several methods for treatment optimization 131 have been identified and used to select tranches of treatment opportunities under a given budget constraint. A first method, a so-called Enumerated Opportunities and Evolutionary Learning (EOEA) method, evaluates all possible candidate treatment locations (often numbering in the 10⁶-10⁸ for modestly sized landscapes) and uses an evolutionary learning algorithm to identify the subset of the potential treatment opportunities that together maximize suitability. This method has been shown to effectively produce treatment recommendations for landscapes of many sizes across California with great computational efficiency.

### Defining Treatment Opportunities

First, all potential treatment opportunities on the landscape are enumerated using geospatial processing and trigonometric relationships to place potential treatments across the fire pathways.

Treatment opportunities can be of any size, and multiple sizes can be used in a single analysis. We focus here on opportunities that are approximately 13.7 acres in size, though we have also seen success with treatments as small as eight acres and as large as 50 acres.

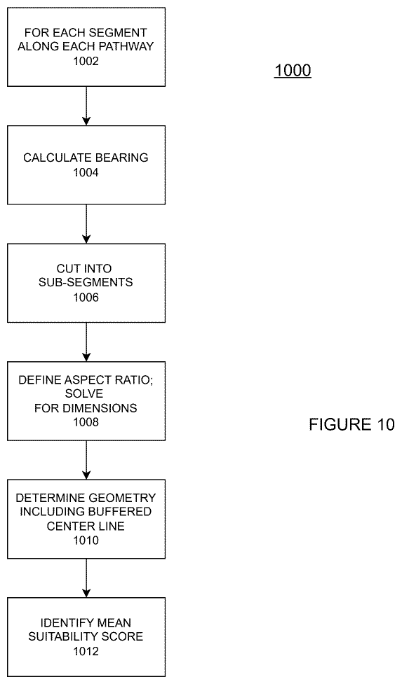

Treatment opportunity placement occurs by iterating through all fire pathways for a given FWS scenario. Referring to FIG. 10, the treatment optimization method 1000 may proceed as follows. For each segment along each pathway (step 1002):

The segment's bearing is calculated (step 1004):
(a) Where:
   and are the latitudes of the two points (in radians),
   is the difference in longitudes (in radians),
   is the two-argument arctangent function that returns the angle in radians between the positive x-axis and the point.

The segment is cut into sub-segments (step 1006) of a given resolution (e.g., 200 meters), and the coordinates of each cut point are calculated as follows:

The total length of the segment between and is given by the Euclidean distance:

The number of sub-segments is the total length divided by the resolution:

Each sub-segment is evenly spaced along the line. The coordinates of each sub-segment point, where, can be calculated as:
for to, where is the starting point and is the endpoint.

Define the aspect ratio (step 1008) of an opportunity as and the area of the opportunity as. Use algebra to solve for the dimensions of an opportunity under a given aspect ratio and area. In most cases, we have seen aspect ratios in the range of 0.5-1 be most successful (i.e., the treatment is wider than it is long).

At each segment cut point, draw a project center line perpendicular to the axis of the pathway, extending ½ of the total width of the treatment opportunity on each side of the pathway.

The bearing of a line perpendicular to the pathway is the negative reciprocal of the segment bearing:

The perpendicular line through each sub-segment point is:

Using a geospatial buffer operation, the perpendicular line is buffered so that it extends meters to either side (along the axis of the pathway).

The geometry of the final buffer operation (step 1010) is retained as the treatment opportunity's geometry.

For each opportunity, zonal statistics are used to identify the mean suitability score (step 1012) for the area within its geometry.

### Defining the Constrained Optimization Problem

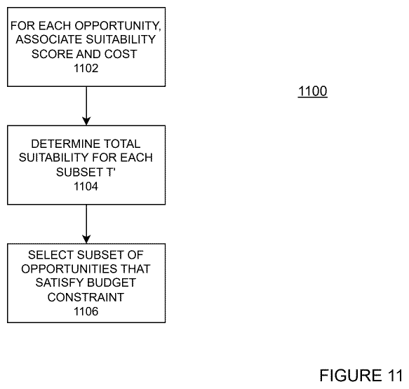

Under a given budget, a certain number of treatment opportunities can be addressed. FIG. 11 is an example flow 1000. Assuming a five-year treatment plan, we first identify a constraint, such as the working budget for a given year, denoted as. The goal of the algorithm is to define a subset of all treatment opportunities, such that the total treatment suitability is maximized while staying within the working budget.

Let each treatment opportunity have an associated suitability score and cost (step 1102). The total suitability of a subset is (step 1104):

The total cost of the subset must not exceed the working budget for the given year. This can be expressed as:

The goal of the algorithm (step 1106) is to select a subset of treatment opportunities that maximize the total treatment suitability while satisfying the budget constraint. Mathematically, this can be written as:
subject to:

### Using Machine Learning to Identify the Optimal Subset

Given that analyses often involve millions or even billions of potential combinations of treatment opportunities, it is not feasible to directly calculate every potential subset. Instead, we employ an evolutionary learning algorithm to also solve the constrained optimization problem (e.g., as part of optimization 131).

### Define the Fitness Function 1200

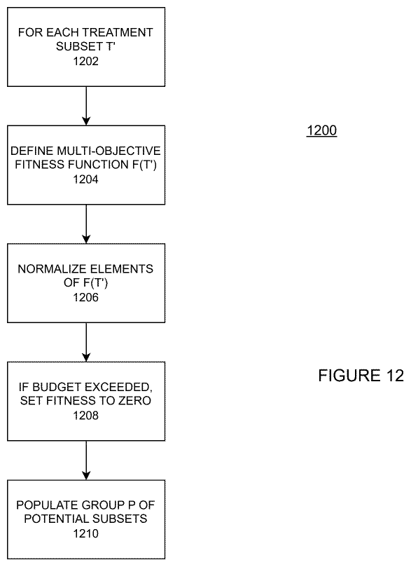

Turning to FIG. 12, for each subset (step 1202), we define a multi-objective fitness function (step 1204) based on three components:

Average suitability score:

Suitability score of the worst opportunity:

The standard deviation of the centroids of the geometries of the subset members. If is the set of centroids of the geometries of the subset, the standard deviation of the centroid locations is:
Where:
   is the mean of the centroids in.

Each of these fitness elements is normalized (step 1206) by the average across the entire distribution of treatment opportunities:
If the subset exceeds the budget, (step 1208) the fitness is set to zero, indicating that it is unsuitable for treatment:

### Initialize the Population

A population of potential subsets is generated (step 1210), where each subset meets the budget constraint:

We have found success in applying the algorithm with an initial population size of 100-500 individual subsets.

### Evolutionary Learning Loop

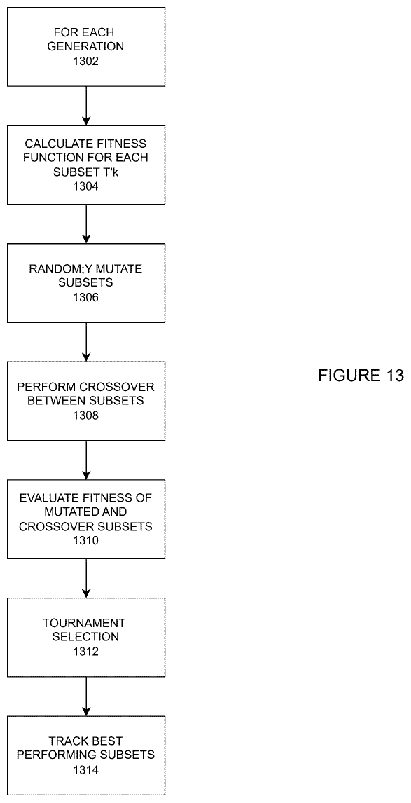

An evolutionary learning loop is then run for a specified number of generations or until a termination condition is reached. An example learning loop 1300 is shown in FIG. 13. For each generation (step 1302):

Calculate the fitness function (step 1304) for each subset using.

Randomly mutate each subset (step 1306) at a rate, by replacing treatment opportunities in the subset with new ones. Let denote the mutated subset.

Perform crossover (step 1308) between two subsets and at a rate, exchanging a portion of the subsets. The new subset is formed by combining parts of both subsets. Several crossover methods were evaluated; good success was achieved with both one- and two-point crossover.

Evaluate the fitness (step 1310) of the new mutated and crossover subsets.

A tournament selection algorithm (step 1312) is used to determine which subsets should be retained in future generations. Tournament selection works by selecting random subsets from the population and choosing the one with the highest fitness. Let the population have fitness values.

For each tournament:
(a) Randomly select subsets from.
(b) Evaluate their fitness: for.
(c) Select the subset with the highest fitness to proceed to the next generation.

Hall of Fame: Keep track of the best-performing subset (step 1314) across all generations, ensuring it is always retained in future generations. This “elitism” ensures that the best individuals from the current generation automatically carry over to the next generation.

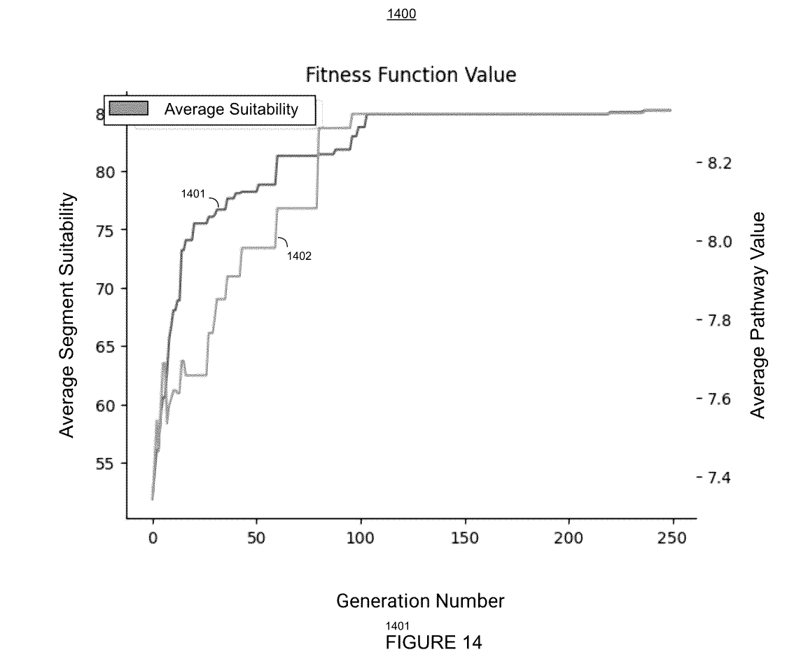

FIG. 14 shows an example 1400 of the fitness components evaluated for 250 iterations of the evolutionary learning algorithm. The blue line 1401 is the objective function/fitness function value which is broader than the suitability value alone and is what the machine learning model optimizes directly. The pink line 1402 is the average suitability of the chosen subset, which is more directly relevant to the user, and is shown to increase as the evolutionary learning algorithm chooses which areas of the landscape to modify.

### Termination Conditions for Evolution

In some embodiments, the evolutionary loop 1300 may be continued until one of the following stopping conditions has been met:

A prespecified number of generations has been run

No significant improvement in fitness after generations, indicating that the algorithm has reached convergence.

### Opportunity Selection—Method 2—Region Growing Algorithm

A second opportunity optimization algorithm 131 does not require that the size and shape of opportunities be determined a priori by the end-user or model developer. Instead, high-suitability key-nodes are identified and used as input into a Region-Growing Algorithm (RGA), where a treatment project geometry is iteratively constructed by evaluating potentially contiguous areas for treatment.

### Considerations for Region Growing:

Treatment Geometry Orientation: The ideal treatment geometries are oriented perpendicular to the axis of fire growth, which is determined by the wind-slope alignment vector. To derive treatment opportunity geometries along this perpendicular bearing, the derivative of the suitability matrix is used. This identifies locations where fire pathways can be “choked off” by treatments, analogous to creating a dam in a river or a speed bump on a road.

Termination Conditions: The region-growing process continues until one of the following conditions is met:

A maximum treatment size has been reached (e.g., 25 acres of treatment).

The suitability of the remaining adjacent nodes falls below a threshold, such as being less than 50% of the average suitability of the already grown region.

### Region Growing Algorithm:

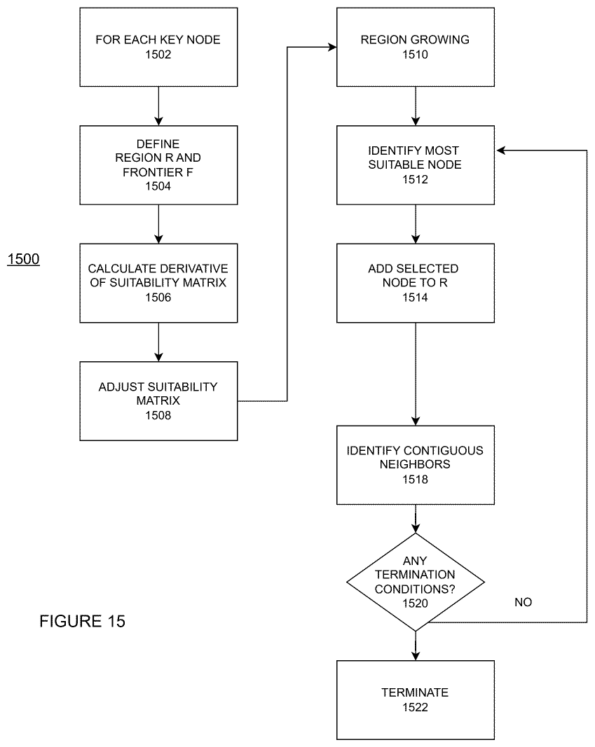

An example region growing flow 1500 is shown in FIG. 15. Key nodes are located by identifying the pathway segment cut points (described in Method 1) with the highest suitability values.

Given a starting key node, the region-growing algorithm proceeds for each such node (step 1502) as follows:

Initialization (step 1504):

Define the region, with as the key node.

Define the frontier, containing nodes neighboring.

### Suitability Adjustment:

Calculate (step 1506) the derivative of the suitability matrix, so that cells perpendicular to the axis of fire growth are more suitable than those in alignment

Adjust (step 1508) the suitability matrix by multiplying the raw suitability values by the derivative:

Additional suitability adjustments: Compared to the EOEA method, the RGA method enables greater flexibility in controlling the properties of the treatment opportunity. Control is achieved by dynamically adjusting the suitability to encourage or discourage the selection of nodes with particular qualities. For example,
(a) Uniform vegetation type: Preference for treatments focusing on a single vegetation type can be achieved by consulting a vegetation type map and adjusting the suitability of candidate nodes that are of a different lifeform of than the key node used to initiate the region growing algorithm.
(b) Uniform land ownership: Preference for treatments residing within a single land owner's jurisdiction or parcel can be achieved by consulting a parcel or land ownership map and adjusting the suitability of candidate nodes that are within a different parcel or jurisdiction than the key node.

Region Growing Loop (step 1510):

Until a termination condition is met:

Identify (step 1512) the most suitable node in the frontier based on the adjusted suitability values.

Add (step 1514) the selected node to R:

Identify new contiguous neighbors (step 1518) of the added node and add them to the frontier.

Check termination conditions (step 1520):

Terminate if the region is sufficiently large:

$${\sum }_{( x , y ) ∈ R} A ( x , y ) \geq {A}_{max}$$

Where:
is the area of the grown region
is a prespecified maximum area for treatment opportunities

Terminate (step 1522) if remaining nodes in the frontier are of poor suitability:
Where:
β is a prespecified scaling factor
If no termination condition is met, repeat (return to step 1512).
Growing a Population of Regions

Regions are iteratively grown until a specified number of iterations have been completed. Each grown region is then subjected to an evaluation method 132 based on performance metrics and used to populate a high-performing population of regions. New regions are generated in each iteration, and poorly performing regions are replaced by new ones based on their performance, allowing the population of regions to converge towards an optimal subset that adheres to the budget constraint.

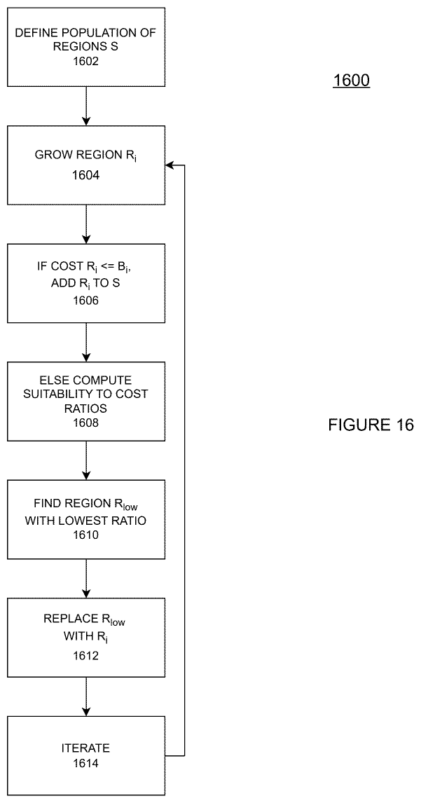

An example process 1600 is shown in FIG. 16. Define (step 1602) the population of regions, initialized as an empty set:

For each iteration:
Grow (step 1602) a region
Check (step 1604) the total cost:
If:
Then, add (step 1606) to the set:
Otherwise, compute (step 1608) the suitability-to-cost ratio for each region:
Find (step 1610) the region with the lowest ratio:
Replace (step 1612) with:
Continue (step 1614) for a specified number of iterations
Evaluating Treatment Plan Impact on Objective Functions (such as Fire Arrival Time)

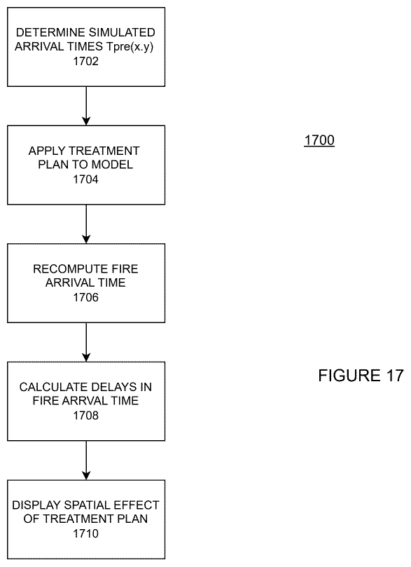

For each tranche, a treatment plan is defined as the population of treatment opportunities selected through one of the methods described above. The effect of the treatment plan on delaying fire arrival in the community is then subjected to evaluation methods 132 that compare fire behavior before and after the treatment. FIG. 17 illustrates the flow of one such evaluation method 1700.

Let (step 1702) be an objective function, such as the simulated fire arrival time at each location before the treatment plan is applied.

After virtually applying (step 1704) the treatment plan, the fire arrival time is recomputed (step 1706) for each location, denoted by.

The delay in fire arrival at each location, structure, or value at risk, located at, is calculated (step 1708) as (e.g., the change in objective function):

Where positive values indicate a delay in fire arrival due to the treatment plan.

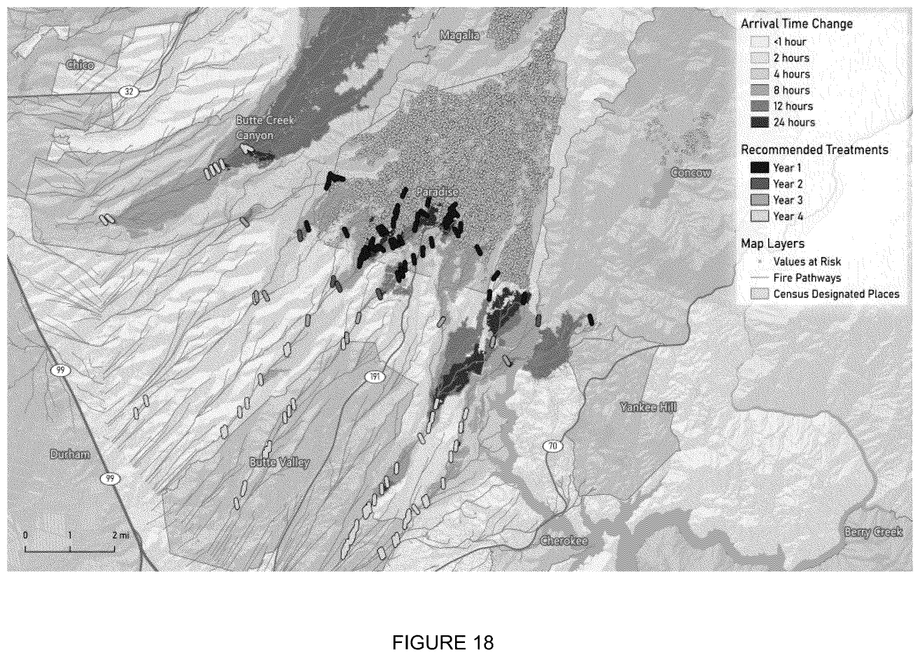

Maps like FIG. 18 can then be drawn (step 1710) to illustrate the spatial effect of the treatment plan on delaying fire growth, showing the difference across the landscape.

It should be understood that other objective functions are possible.

The delay in fire arrival time attributable to a particular treatment plan, such as a four-year treatment plan for the Paradise CA example already mentioned above, can be determined using the EOEA method described above. FIG. 18 is an example showing the resulting delay in fire arrival time with application of the recommended treatments.

### Termination Conditions

The evaluation methods 132 may also iteratively add tranches of treatment opportunities to the landscape while assessing the impact of each tranche on arrival time. The goal is to maximize the effectiveness of the overall treatment plan while remaining within the budget set forth by the user.

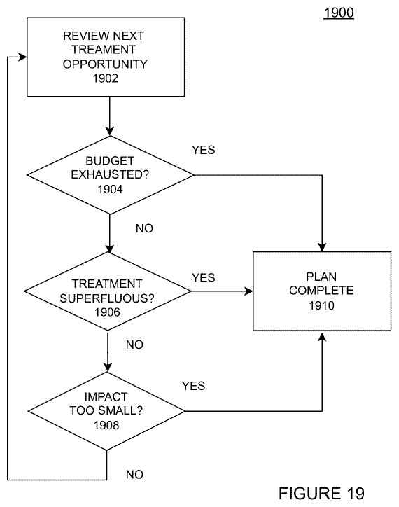

Referring to an example method 1900 as per FIG. 19, a treatment opportunity is identified (step 1902). A tranche process continues until a stopping condition is met:

The overall budget has been exhausted (step 1904): Given a total budget with which to implement the overall treatment project, all tranches of treatments must have a total aggregated cost of less than.

The cost of implementing tranche is defined as, therefore, the aggregated cost of all tranches is

Therefore, the algorithm is terminated (step 1910) if.

The simulated fire no longer reaches the community's values at risk within the specified time frame, making additional treatments superfluous (step 1906) in delaying fire arrival.

Each simulation is run for a given amount of time, given by, which is specified by the model developer and usually ranges from 8-24 hours.

Defining the post-treatment fire arrival time as after applying tranche, the algorithm is terminated (step 1910) if.

The marginal impact of additional treatment tranches is too small (step 1908).

Given a set of values at risk, the marginal impact of a tranche of treatments is defined as
Where
is the change in fire arrival time at value at risk before and after the treatments in tranche are applied; and
   |V| is the number of values at risk.
If the marginal impact of a tranche is less than a prespecified minimum value (in percentage or absolute terms), then the algorithm is terminated (step 1910).
Formally,
Where
is a prespecified value chosen by the model developer, for example, 15 minutes.

### Inclusion in a Decision Support System

The algorithm(s) described above can be integrated into a decision support system that supplies novel. high-return-on-investment treatment plans to vegetation management specialists. These specialists may be working in local and regional fire departments, land management agencies, fire-focused non-governmental organizations, and other entities charged with mitigating fire risk for communities.

### Structure of the an Example System Application

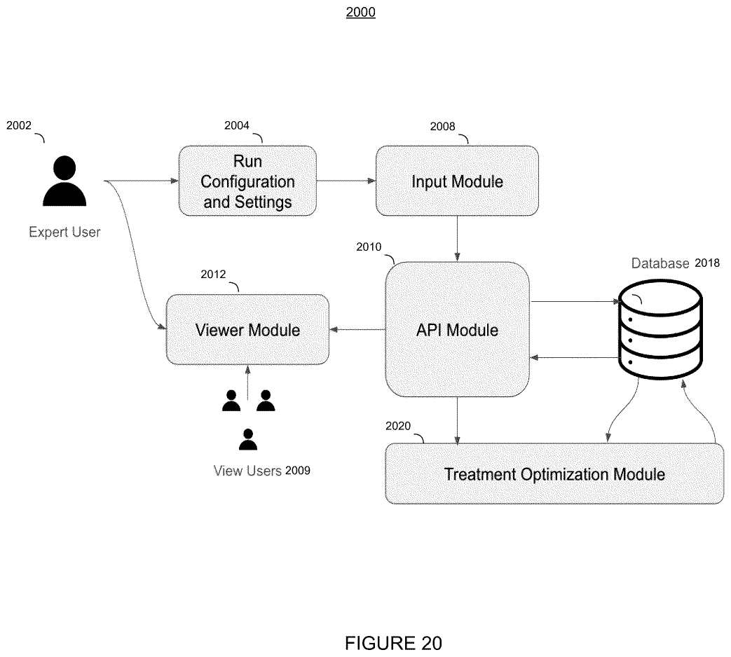

An example web-based application is shown in FIG. 20. It includes the following components:

Input Module 2008: A web interface that allows users to specify settings related to the treatment optimization project. Configurable settings include:
(a) Project area/area of analysis
(b) Maximum budget
(c) Values at risk
(d) Cost per acre of treatment
(e) Fire weather scenarios

Core Databases 2018: One or more cloud-enabled spatial database(s) that store run metadata, configuration, and treatment plan results, including geometries of each proposed treatment opportunity.

Treatment Optimization Module 2020: A Python-based implementation of the modules functions and algorithms described above, including one or more of the following:
(a) Downloads requisite datasets (171, 172, 173) from various publicly available sources and databases
(b) Preprocesses the datasets to facilitate treatment optimization analysis 130
(c) Runs fire pathways 110 under the user-provided fire weather scenarios
(d) Performs risk assessment 120 including scoring 121 and against conflagration models 122
(e) Creates post-treatment landscapes and computes the differences between pre- and post-treatment fire behavior (evaluation 132)
(f) Develops treatment opportunities 131
(g) Iteratively constructs treatment plans through the tranche method described above 132.
(h) Stores model output in the database, along with other run metadata.

Application Programming Interface (API) Module 2010: A Python-based application that receives and responds to requests over the HTTP protocol, responsible for:
(a) Receiving requests for new treatment optimization runs
(b) Queuing new treatment optimization run requests
(c) Storing user-provided configuration and metadata to the database
(d) Returning responses to the user interface

Results Viewer Module 2012: A web application that allows the user to view, understand, and interrogate results from the treatment optimization module 2020. Basic functions include:
(a) Load a previously configured treatment optimization plan
(b) View the plan geometry on the map, symbolized by the recommended priority
(c) Load and display additional contextual datasets, such as arrival time change, wind speed, wind direction, fuel and vegetation type, topography, and recent landscape disturbances, such as fire, disease, and management activities.
(d) Animate fire pathways to show fire growth and the influence of the proposed vegetation management plan.
(e) Toggle layers on and off on a map view
(f) View basic statistics about the recommended treatment plan
(g) View spatial relationships between the treatment plan, the fire pathways, and a community's values at risk.
(h) View the suitability for treatment at all points on the landscape.
(i) View fire pathways and animated fire growth in a 3-dimensional experience
(j) Toggle between multiple basemap with different contextual layers, such as satellite imagery and a thematic basemap.

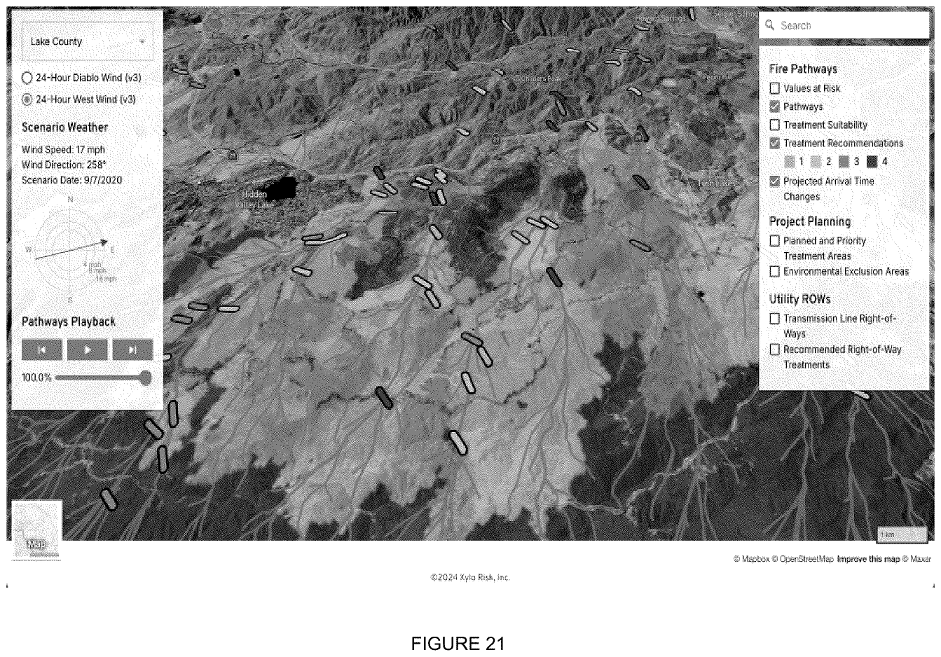

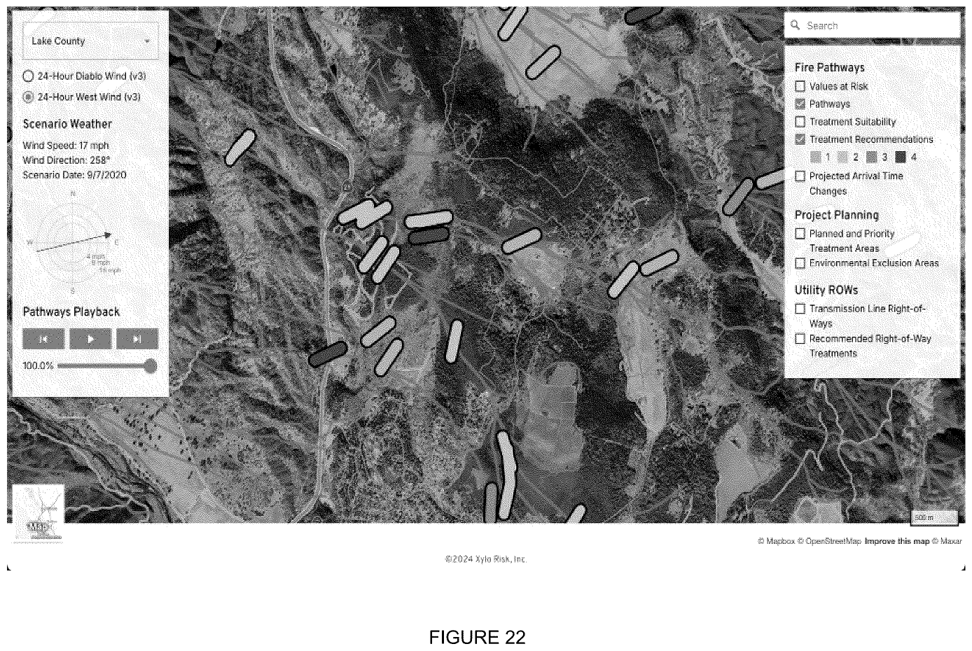

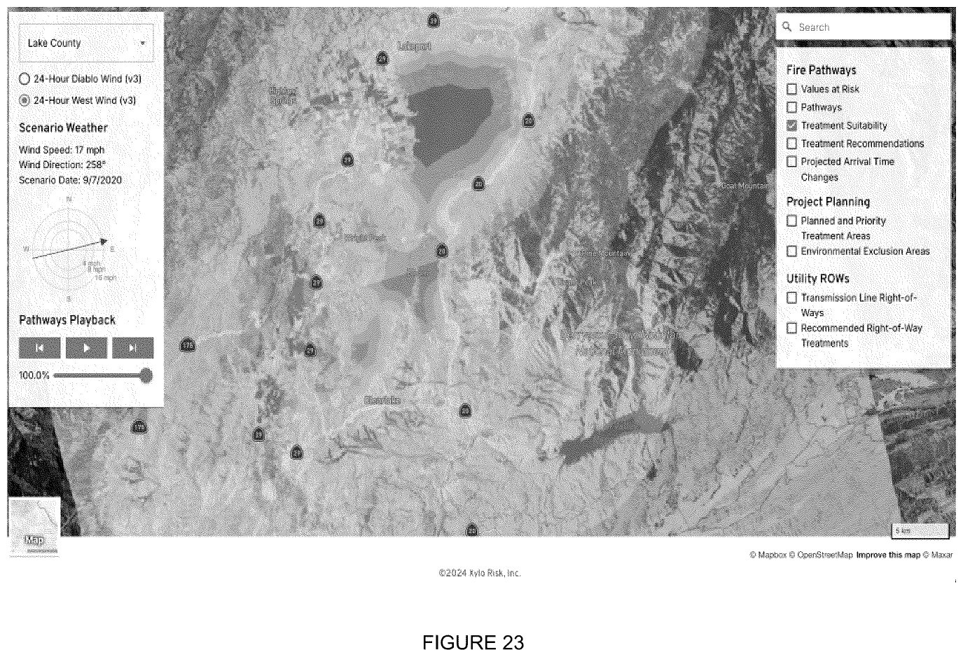

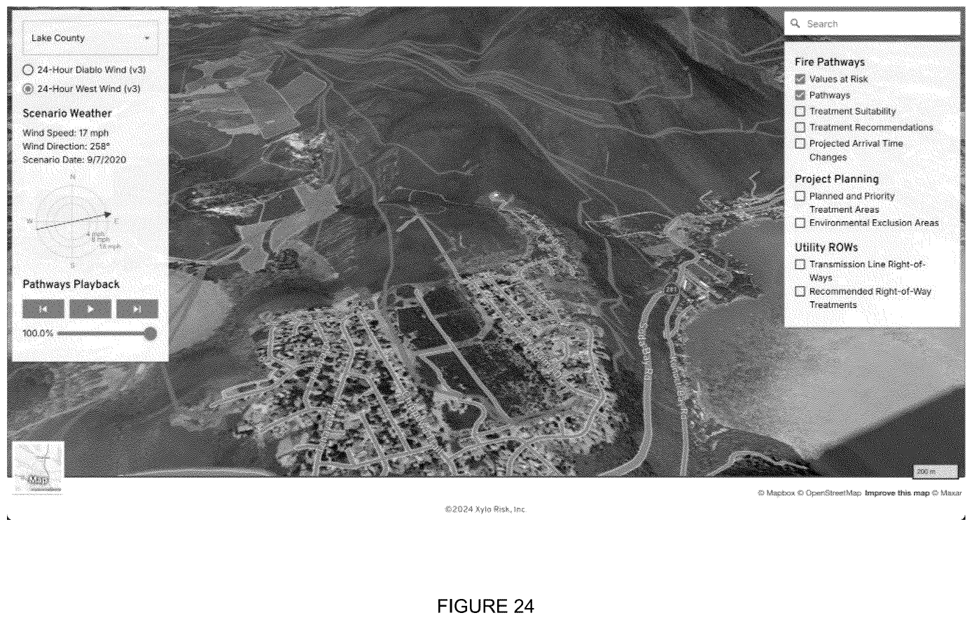

FIGS. 21-24 show several examples of the user interface in action. The presentation of these interfaces is organized as follows:
(left legend) Fire weather configuration, including wind speed, direction, and a representative date. Additionally, the “pathways playback” interface provides the ability to animate the results, enabling users to have a better sense of how the fire evolve with/without the implementation of the vegetation management over time.
(middle) A map, including fire pathways (orange) and the recommended vegetation management areas (colored polygons). As indicated on the legend in the right, these polygons have colors that correspond to different priority ranks, as determined by the sequential/tranche algorithm(s).
(right legend) The color legend for the map, and the input toggles for enabling or disabling contextual layers. The toggles improve the ability for this to be used in a decision support context along with other spatial layers.

FIG. 21 is the interface with fire pathways, treatment recommendations, and projected arrival time enabled, at a 1 km scale.

FIG. 22 is the interface with fire pathways, and treatment recommendations enabled, at a 500 m scale.

FIG. 23 is the interface showing suitability values for each location on the landscape, ranging from blue (highest) to red (lowest), at a 5 km scale.

FIG. 24 is the interface with a rendering of fire pathways and values at risk, at a 200 m scale, and from yet another viewpoint.

### Further Implementation Options

It should be understood that the workflows of the example embodiments described above may be implemented in many different ways. In some instances, one or more “data processors” may each be implemented by a physical or virtual or cloud-based general purpose computer having a central processor, memory, disk or other mass storage, communication interface(s), input/output (I/O) device(s), and other peripherals. The general-purpose computer(s) are transformed into the processors and execute the processes described above, for example, by loading software instructions, and then causing execution of the instructions to carry out the functions described. If there are more than one data processor, they cooperate to execute the functions.

As is known in the art, each such data processor may contain a system bus, where a bus is a set of hardware lines used for data transfer among the components of a computer or processing system. The bus or busses are essentially shared conduit(s) that connect different elements of the computer system (e.g., one or more central processing units, disks, various memories, input/output ports, network ports, etc.) that enables the transfer of information between the elements. One or more central processor units are attached to the system bus and provide for the execution of computer instructions. Also attached to system bus are typically I/O device interfaces for connecting the disks, memories, and various input and output devices. Network interface(s) allow connections to various other devices attached to a network. One or more memories provide volatile and/or non-volatile storage for computer software instructions and data used to implement an embodiment. Disks or other mass storage provides non-volatile storage for computer software instructions and data used to implement, for example, the various procedures described herein.

Embodiments may also be implemented in hardware, custom designed semiconductor logic, Application Specific Integrated Circuits (ASICs), Field Programmable Gate Arrays (FPGAs), firmware, software, or any combination thereof.

In certain embodiments, the procedures, devices, and processes described herein are a computer program product, including a non-transitory computer readable medium (e.g., a removable storage medium such as one or more DVD-ROM's, CD-ROM's, Flash, diskettes, tapes, etc.) that provides at least a portion of the software instructions for the system. Such a computer program product can be installed by any suitable software installation procedure, as is well known in the art. In another embodiment, at least a portion of the software instructions may also be downloaded over a cable, communication and/or wireless connection.

Embodiments may also be implemented as instructions stored on a non-transient machine-readable medium, which may be read and executed by one or more procedures. A non-transient machine-readable medium may include any mechanism for storing or transmitting information in a form readable by a machine (e.g., a computing device). For example, a non-transient machine-readable medium may include read only memory (ROM); random access memory (RAM); storage including magnetic disk storage media; optical storage media; flash memory devices; and others.

Embodiments may also leverage cloud data processing services such as Amazon Web Services, Google Cloud Platform, and similar tools. Accordingly, further embodiments may also be implemented in a variety of computer architectures, physical, virtual, cloud services, and/or some combination thereof, and thus the data processing systems described herein are intended for purposes of illustration only and not as a limitation of the embodiments.

Furthermore, firmware, software, routines, or instructions may be described herein as performing certain actions and/or functions. However, it should be appreciated that such descriptions contained herein are merely for convenience and that such actions in fact result from computing devices, processors, controllers, or other devices executing the firmware, software, routines, instructions, etc.

It also should be understood that the flow, block and system diagrams may include more or fewer elements, be arranged differently, or be represented differently. But it further should be understood that certain implementations may dictate the block and network diagrams and the number of block and network diagrams illustrating the execution of the embodiments be implemented in a particular way.

The above description has particularly shown and described example embodiments. However, it will be understood by those skilled in the art that various changes in form and details may be made therein without departing from the legal scope of this patent as encompassed by the appended claims.

We claim:

1. A decision support system for wildfire risk mitigation, the system comprising:
one or more processors;
a non-transitory memory storing instructions that, when executed by the one or more processors, cause the one or more processors to:
(i) receive and store a plurality of candidate treatment plans for a geographic region, each treatment plan comprising a set of treatment actions associated with a geographic footprint, an implementation cost, and an anticipated effect on fire spread;
(ii) access a directed graph representation of filtered fire spread pathways, the directed graph comprising nodes corresponding to cell and time states and edges corresponding to transitions with associated propagation likelihoods and incremental losses;
(iii) simulate, for each treatment plan, a modified set of fire spread pathways by applying an effect model that adjusts propagation likelihoods and incremental losses for edges intersecting the treatment actions of the treatment plan;
(iv) compute, for each treatment plan, a suitability score based on
(a) an expected risk reduction derived from the modified set of fire spread pathways, and/or
(b) implementation cost of the treatment plan;
(v) rank the plurality of treatment plans based on the suitability scores to produce ranked treatment plans;
(vi) generate a decision support output comprising the ranked treatment plans and corresponding geospatial overlays for display in a user interface; and
(vii) receive user adjustments to one or more decision parameters, the decision parameters comprising at least a budget constraint, a risk-reduction weighting factor, or a geographic priority, wherein the one or more processors are further configured to recompute the suitability scores and the ranked treatment plans in response to the user adjustments.

2. The system of claim 1 wherein the effect model for a given treatment action changes fire behavior characteristics and reduces a propagation likelihood of each affected edge by a physically-based factor and/or increases an associated traversal cost.

3. The system of claim 1 wherein computing the suitability score comprises normalizing the expected risk reduction by implementation cost to generate a cost-effectiveness ratio.

4. The system of claim 1 wherein simulating the modified set of fire spread pathways comprises executing a Monte Carlo simulation over an ensemble of weather scenarios.

5. The system of claim 1 wherein the plurality of candidate treatment plans are generated by an optimization module, configured to maximize expected risk reduction subject to a budget constraint.

6. The system of claim 1 wherein the decision support output further comprises an explanation layer that associates each ranked treatment plan with one or more dominant fire spread pathways mitigated by the plan.

7. A computer-implemented method for wildfire risk mitigation planning, the method comprising:
(a) receiving, by one or more processors, multi-source geospatial and temporal data for a geographic region divided into cells, the data comprising at least weather fields, topography, vegetation data, fuel condition data, and asset exposure data;
(b) simulating, given candidate ignition locations and over a time-indexed directed graph, a plurality of fire spread pathways using a fire spread model to produce, for each such pathway, an ordered sequence of cell transitions with associated propagation likelihoods and intensity estimates;
(c) computing, for each fire spread pathway, an impact score based at least on the associated propagation likelihoods and exposure of assets intersected by the respective pathway;
(d) defining a library of candidate treatment actions, each treatment action comprising a geographic footprint mapped to a subset of nodes or edges in the directed graph, an effect model specifying at least a reduction in propagation likelihood on affected edges, and an implementation cost;
(e) evaluating, for each candidate treatment action and at least one combination of candidate treatment actions, a risk-reduction value computed as a change in expected loss on the directed graph when applying the effect model to the subset of nodes or edges associated with the candidate treatment action(s);
(f) selecting, from the candidate treatment actions, a treatment plan comprising a subset of the candidate treatment actions that maximizes a risk-reduction objective subject to one or more constraints comprising a budget constraint and at least one resource, geographic, or timing constraint;
(g) generating, from the data, a time-indexed spatial representation of the geographic region comprising a plurality of cells at a temporal resolution and identifying a set of candidate ignition locations for a selectable forecast horizon; and
(h) outputting the treatment plan together with geospatial identifiers and scheduling information to a planning interface for execution.

8. The method of claim 7 additionally comprising:
filtering the plurality of fire spread pathways by removing one or more pathways:
(i) having a propagation likelihood below a threshold,
(ii) that are dominated pathways based on a multi-criteria dominance test using probability and impact, or
(iii) are duplicate pathways based on path-overlap similarity.

9. The method of claim 8 additionally comprising:
constructing, from the filtered fire spread pathways, a directed graph comprising nodes representing respective locations and edges representing transitions between states in the directed graph, each edge annotated with a propagation likelihood and an asset exposure value.

10. The method of claim 7 additionally comprising:
treatment optimization using an evolutionary learning algorithm to generate a population of potential treatment opportunities, and to select an optimal treatment set based on a fitness function that incorporates fire arrival times, structure risk, and budget constraints.

11. The method of claim 7 additionally comprising:
operating a cloud-based backend and database to implement one or more steps of the method.

12. The method of claim 7 additionally comprising:
accessing a spatially-explicit Parcel Database, for further evaluation of each candidate action by promoting treatments that span a limited number of parcels.

13. The method of claim 7 wherein the data is augmented with a spatially-explicit Vegetation Database, and the evaluation of each candidate action is dynamically adjusted to promote treatments that span a single vegetation type.

14. The method of claim 7 wherein evaluating the mitigation actions comprises solving an optimization problem that enforces one or more resource, temporal, or geographic constraints.

15. The method of claim 7 additionally comprising:
operating a user interface that renders a geospatial visualization comprising calibrated risk values, corresponding uncertainty values, and an actionable task plan as separate interactive layers.

16. The method of claim 7 wherein computing the impact score comprises normalizing the expected risk reduction by an implementation cost to generate a cost-effectiveness ratio.

17. The method of claim 7 additionally comprising:
generating decision support output comprising an interactive geospatial visualization that displays ranked treatment plans, with selectable layers showing geographic footprints of treatment actions and predicted reductions in fire spread.

18. The method of claim 7 wherein the plurality of candidate treatment plans are generated by maximizing expected risk reduction subject to a budget constraint prior to ranking.
